(19) United States
(12) Patent Application Publication
(10) Pub. No.: US 2026/0009771 A1
(43) Pub. Date: Jan. 8, 2026

(54) APPARATUS FOR DIAGNOSING STATE OF BATTERY AND METHOD THEREOF

(71) Applicants: HYUNDAI MOTOR COMPANY, Seoul (KR); KIA CORPORATION, Seoul (KR); CAMMSYS Corp., Incheon (KR)

(72) Inventors: Yoo Hong Jang, Hwaseong-si (KR); Ki Young Lee, Hwaseong-si (KR); Myung Jin Kim, Hwaseong-si (KR); Young Hyun Lee, Hwaseong-si (KR)

(73) Assignees: HYUNDAI MOTOR COMPANY, Seoul (KR); KIA CORPORATION, Seoul (KR); CAMMSYS Corp., Incheon (KR)

(21) Appl. No.: 18/915,891

(22) Filed: Oct. 15, 2024

(30) Foreign Application Priority Data
Jul. 5, 2024 (KR) 10-2024-0089031

(51) Int. Cl. G01N 29/44; H01M 10/42

(52) U.S. Cl. CPC G01N 29/4427; H01M 10/4285

(57) ABSTRACT

Disclosed are an apparatus for diagnosing a state of a battery and a method thereof. The apparatus includes an ultrasonic sensor that generates an ultrasonic signal on one side of the battery and receives an ultrasonic signal transmitted through the battery from an opposite side of the battery, and a controller that detects a signal amplitude (SA) based on the ultrasonic signal, determines a state of health (SOH) of the battery, determines total energy of the battery by using a lifespan curve corresponding to the SOH and SA of the battery, and determines a residual value of the battery based on the total energy of the battery.

### CROSS-REFERENCE TO RELATED APPLICATION

This application claims the benefit of priority to Korean Patent Application No. 10-2024-0089031, filed in the Korean Intellectual Property Office on Jul. 5, 2024, the entire contents of which are incorporated herein by reference.

### TECHNICAL FIELD

The present disclosure relates to technology for diagnosing a state of a battery provided in an electric vehicle or an energy storage system (ESS).

### BACKGROUND

In general, an electric vehicle, which is a vehicle driven by electric energy, is equipped with a battery including a plurality of battery cells that store electric energy. Such battery cells convert chemical energy into electrical energy to supply electrical energy (i.e., discharge), or convert electrical energy supplied from outside into chemical energy to store it (i.e., charge).

Because an electric vehicle is driven using electrical energy stored in a battery as a power source, the performance of the vehicle is determined by the performance of the battery. Therefore, in order to improve the performance of an electric vehicle, it is useful to manage the battery to maximize the performance.

In recent years, because battery cells with high performance are used to improve the power source of a vehicle and the number of battery cells used has been growing, it is increasingly important to manage a battery. Such battery management is generally performed by a battery management system (BMS).

The BMS measures cell state information including a voltage, a current, a temperature, and the like of a battery cell from a battery module provided in an electric vehicle, uses the cell state information and option values for controlling battery cells to manage the battery cells, and performs cell balancing to maintain balance between the battery cells.

The cell balancing is one of the control operations of a battery management system that equalizes the voltages or charge amounts of battery cells. Each battery cell of a battery module may have differences in electrical characteristics even when the battery cells are manufactured under the same manufacturing conditions and environment, and may also have differences in electrical characteristics even when the battery cells are mounted and operated in an electric vehicle.

Due to such differences in electrical characteristics, even when battery cells are charged and discharged with the same current, voltage imbalance or residual charge imbalance may occur between interconnected battery cells, and the voltage imbalance or residual charge imbalance between battery cells may cause the available voltage range of battery cells to decrease or the charging and discharging cycle to be shorter.

Meanwhile, as the number of scrapped electric vehicles increases rapidly, there are active discussions on how to utilize the batteries provided in the electric vehicles, and as a technology for supporting it, a technology that can diagnose the condition of a battery has been developed.

For reference, a used battery may be reused, remanufactured, or recycled depending on the residual value. In this case, reuse means that the used battery has good performance and is reused in other electric vehicles, and remanufacturing means dismantling used batteries into modules and remanufacturing modules with good performance into batteries suitable for other devices (e.g. drones, golf carts, and the like). In addition, recycling means disassembling the battery into cells at the end of its life, extracting rare earth metals (e.g., cobalt, lithium, nickel, manganese, and the like) and re-injecting them into the production of new batteries.

As described above, used batteries may be used in various manners depending on their residual value. However, so far, it is only possible to diagnose the deterioration of a used battery or whether the used battery is reusable. In reality, no method has been proposed to diagnose how much the residual value of a used battery is or specifically whether a used battery is applicable to a system requiring a specified level of output.

The matters described in this background section are intended to promote an understanding of the background of the disclosure and may include matters that are not already known to those of ordinary skill in the art.

### SUMMARY

The present disclosure has been made to solve the above-mentioned problems occurring in the prior art while advantages achieved by the prior art are maintained intact.

One aspect of the present disclosure provides an apparatus for diagnosing a state of a battery and a method thereof capable of determining whether to reuse, remanufacture, or recycle the battery by obtaining an ultrasonic signal from the battery by using an ultrasonic sensor, detecting a signal amplitude (SA) and a time of flight (ToF) based on the ultrasonic signal, determining a state of health (SOH) of the battery, determining a lifespan curve corresponding to the SOH, SA, and ToF of the battery, determining the total energy of the battery by using the lifespan curve, and determining a residual value of the battery based on the total energy of the battery.

Another aspect of the present disclosure provides an apparatus for diagnosing a state of a battery and a method thereof capable of providing a system environment in which the battery is applied by obtaining a plurality of first ultrasonic signals in the process of charging the battery, obtaining a plurality of second ultrasonic signals in the process of discharging the battery, detecting a minimum signal amplitude (SA) based on the plurality of first ultrasonic signals, detecting a maximum SA based on the plurality of second ultrasonic signals, determining the state of health (SOH) of the battery, and determining a maximum current corresponding to the SOH, maximum SA, and minimum SA of the battery.

Still another aspect of the present disclosure provides an apparatus for diagnosing a state of a battery and a method thereof capable of providing a system environment in which a target battery is applied by obtaining a plurality of first ultrasonic signals in the process of charging the battery with a look-up table in which the maximum current corresponding to the state of health (SOH), maximum signal amplitude (SA) and minimum SA of the battery is recorded, obtaining a plurality of second ultrasonic signals in the process of discharging the battery, detecting the minimum SA based on the plurality of first ultrasonic signals, detecting a maximum SA based on the plurality of second ultrasonic signals, determining the SOH of the battery, and determining a maximum current of the target battery based on the lookup table.

The technical problems to be solved by the present disclosure are not limited to the aforementioned problems, and any other technical problems not mentioned herein will be clearly understood from the following description by those skilled in the art to which the present disclosure pertains. Also, it may be easily understood that the objects and advantages of the present disclosure may be realized by the units and combinations thereof recited in the claims.

According to an aspect of the present disclosure, an apparatus for diagnosing a state of a battery includes an ultrasonic sensor that generates an ultrasonic signal on one side of the battery and receives an ultrasonic signal transmitted through the battery from an opposite side of the battery, and a controller that detects a signal amplitude (SA) based on the ultrasonic signal, determines a state of health (SOH) of the battery, determines total energy of the battery by using a lifespan curve corresponding to the SOH and SA of the battery, and determines a residual value of the battery based on the total energy of the battery.

According to an embodiment, the apparatus may further include a memory that stores a plurality of lifespan curves corresponding to the SOH and SA.

According to an embodiment, the controller may select the lifespan curve corresponding to the SOH and SA of the battery.

According to an embodiment, the controller may determine the residual value of the battery as one of a reuse grade, a remanufacturing grade, and a recycling grade.

According to an embodiment, the reuse grade may refer to a state in which the battery is reusable in an electric vehicle, the remanufacturing grade may refer to a state in which the battery is usable in devices other than the electric vehicle, and the recycling grade may refer to a state in which a lifespan of the battery expires and the battery is usable in producing a new battery.

According to an embodiment, the controller may determine the residual value of the battery to be lower than when gas is not generated in the battery, taking into account that the SA is reduced when the gas is generated inside the battery.

According to another aspect of the present disclosure, a method of diagnosing a state of a battery includes generating, by an ultrasonic sensor, an ultrasonic signal on one side of the battery and receiving an ultrasonic signal transmitted through the battery from an opposite side of the battery, detecting, by a controller, a signal amplitude (SA) based on the ultrasonic signal, determining, by the controller, a state of health (SOH) of the battery, determining, by the controller, total energy of the battery by using a lifespan curve corresponding to the SOH and SA of the battery, and determining, by the controller, a residual value of the battery based on the total energy of the battery.

According to an embodiment, the method may further include storing, by a memory, a plurality of lifespan curves corresponding to the SOH and SA.

According to an embodiment, the determining of the total energy of the battery may include selecting, by the controller, the lifespan curve corresponding to the SOH and SA of the battery.

According to an embodiment, the determining of the residual value of the battery may include determining the residual value of the battery as one of a reuse grade, a remanufacturing grade, and a recycling grade.

According to an embodiment, the reuse grade may refer to a state in which the battery is reusable in an electric vehicle, the remanufacturing grade may refer to a state in which the battery is usable in devices other than the electric vehicle, and the recycling grade may refer to a state in which a lifespan of the battery expires and the battery is usable in producing a new battery.

According to an embodiment, the determining of the residual value of the battery may include determining the residual value of the battery to be lower than when gas is not generated in the battery, taking into account that the SA is reduced when the gas is generated inside the battery.

According to still another aspect of the present disclosure, an apparatus for diagnosing a state of a battery includes an ultrasonic sensor that generates an ultrasonic signal on one side of the battery and receives an ultrasonic signal transmitted through the battery from an opposite side of the battery, and a controller that obtains a plurality of first ultrasonic signals while charging the battery, obtains a plurality of second ultrasonic signals while discharging the battery, detects a minimum signal amplitude (SA) based on the plurality of first ultrasonic signals, detects a maximum SA based on the plurality of second ultrasonic signals, determines a state of health (SOH) of the battery, and determines a maximum current corresponding to the SOH, maximum SA, and minimum SA of the battery.

According to an embodiment, the apparatus may further include a memory that stores a look-up table in which a maximum current corresponding to the SOH, the maximum SA, and the minimum SA is recorded.

According to an embodiment, the controller may determine the maximum current corresponding to the SOH, maximum SA, and minimum SA of the battery based on the look-up table.

According to an embodiment, the apparatus may further include an output device that outputs the maximum current.

According to still another aspect of the present disclosure, a method of diagnosing a state of a battery includes generating, by an ultrasonic sensor, an ultrasonic signal on one side of the battery and receiving an ultrasonic signal transmitted through the battery from an opposite side of the battery, obtaining, by a controller, a plurality of first ultrasonic signals while charging the battery and obtaining a plurality of second ultrasonic signals while discharging the battery, detecting, by the controller, a minimum signal amplitude (SA) based on the plurality of first ultrasonic signals, and detecting a maximum SA based on the plurality of second ultrasonic signals, determining, by the controller, a state of health (SOH) of the battery, and determining, by the controller, a maximum current corresponding to the SOH, maximum SA, and minimum SA of the battery.

According to an embodiment, the method may further include storing, by a memory, a look-up table in which a maximum current corresponding to the SOH, the maximum SA, and the minimum SA is recorded.

According to an embodiment, the determining of the maximum current may include determining the maximum current corresponding to the SOH, maximum SA, and minimum SA of the battery based on the look-up table.

According to an embodiment, the method may further include outputting, by an output device, the maximum current.

### BRIEF DESCRIPTION OF THE DRAWINGS

The above and other objects, features and advantages of the present disclosure will be more apparent from the following detailed description taken in conjunction with the accompanying drawings:

FIG. 1 is a block diagram illustrating an apparatus for diagnosing a state of a battery according to an embodiment of the present disclosure;

FIGS. 2A and 2B are diagrams illustrating examples of various scenarios stored in the storage of an apparatus for diagnosing a state of a battery according to an embodiment of the present disclosure;

FIG. 3 is a graph illustrating an example of a lifespan curve corresponding to each scenario stored in the storage of an apparatus for diagnosing a state of a battery according to an embodiment of the present disclosure;

FIG. 4 is a diagram illustrating an example of the intensity of an ultrasonic signal when gas is generated inside a battery;

FIGS. 5A and 5B are diagrams illustrating examples of a lookup table stored in the storage of an apparatus for diagnosing a state of a battery according to an embodiment of the present disclosure;

FIG. 6 is a graph illustrating an example of a process in which a controller provided in an apparatus for diagnosing a state of a battery according to an embodiment of the present disclosure detects the SA and ToF based on an ultrasonic signal of a battery;

FIG. 7 is a graph illustrating an example of a process in which a controller provided in an apparatus for diagnosing a state of a battery according to an embodiment of the present disclosure determines the total energy of the battery;

FIG. 8 is a graph illustrating another example of a process in which a controller provided in an apparatus for diagnosing a state of a battery according to an embodiment of the present disclosure determines the total energy of the battery;

FIG. 9 is a flowchart illustrating a method of diagnosing a state of a battery according to an embodiment of the present disclosure;

FIG. 10 is a flowchart illustrating a method of diagnosing a state of a battery according to another embodiment of the present disclosure; and

FIG. 11 is a block diagram illustrating a computing system for executing a method of diagnosing a state of a battery according to each embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical or equivalent component is specified by the identical numeral even when they are displayed on other drawings. Further, in describing the embodiment of the present disclosure, a detailed description of the related known configuration or function will be omitted when it is determined that it interferes with the understanding of the embodiment of the present disclosure.

In addition, terms, such as first, second, A, B, (a), (b) or the like may be used herein when describing components of the present disclosure. The terms are provided only to distinguish the elements from other elements, and the essences, sequences, orders, and numbers of the elements are not limited by the terms. In addition, unless defined otherwise, all terms used herein, including technical or scientific terms, have the same meanings as those generally understood by those skilled in the art to which the present disclosure pertains. The terms defined in the generally used dictionaries should be construed as having the meanings that coincide with the meanings of the contexts of the related technologies, and should not be construed as ideal or excessively formal meanings unless clearly defined in the specification of the present disclosure.

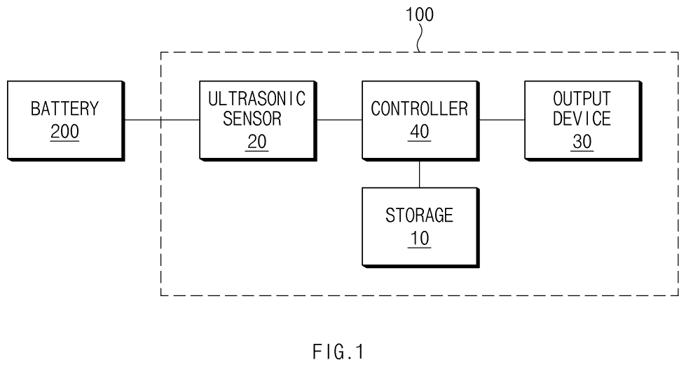

FIG. 1 is a block diagram illustrating an apparatus for diagnosing a state of a battery according to an embodiment of the present disclosure.

As shown in FIG. 1, an apparatus for diagnosing a state of a battery according to an embodiment of the present disclosure may include storage 10, an ultrasonic sensor 20, an output device 30, and a controller 40. In this case, depending on a scheme of implementing an apparatus 100 for diagnosing a state of a battery according to an embodiment of the present disclosure, components may be combined with each other to be implemented as one, or some components may be omitted.

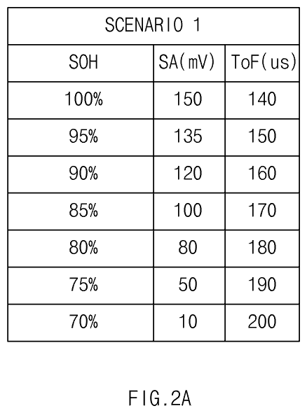

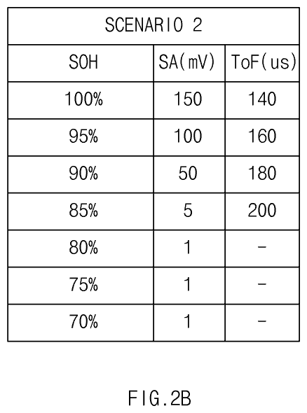

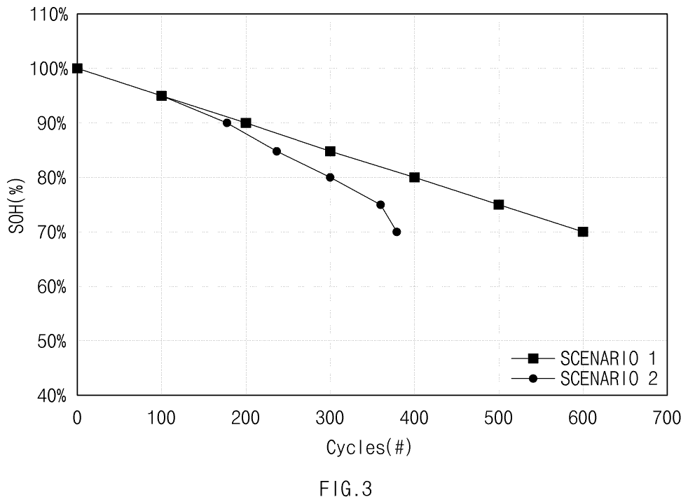

Regarding each component, first, the storage 10 may store a lifespan curve corresponding to a state of health (SOH), a signal amplitude (SA), and a time of flight (ToF) of a battery 200. In this case, the scenarios corresponding to the SOH, SA, and ToF of a general battery are shown in FIGS. 2A and 2B, and the lifespan curves corresponding to each scenario are shown in FIG. 3.

FIGS. 2A and 2B are diagrams illustrating examples of various scenarios stored in the storage of an apparatus for diagnosing a state of a battery according to an embodiment of the present disclosure. Scenario 1 and scenario 2 are explained as examples, but the number of scenarios may increase depending on the charging rate, driving rate, and temperature ratio.

As shown in FIGS. 2A and 2B, when the slow charging (e.g., 11 hours to full charge) ratio is 100%, the fast charging (e.g., 80% charging in 1 hour) ratio is 0%, the general driving (e.g., less than 100 km/h) ratio is 100%, the high-speed driving (e.g., 100 km/h or more) ratio is 0%, the low temperature (e.g., −20° C.) ratio is 20%, the room temperature (e.g., 25° C.) ratio is 80%, and the high temperature (e.g., 45° C.) ratio is 0%, scenario 1 (FIG. 2A) represents the relationship between the SOH, SA, and ToF of a general battery.

When the slow charging ratio is 20%, the fast charging ratio is 80%, the normal driving ratio is 50%, the high-speed driving ratio is 50%, the low temperature ratio is 0%, the room temperature ratio is 50%, and the high temperature ratio is 50%, scenario 2 (FIG. 2B) represents the relationship between the SOH, SA, and ToF of a general battery.

FIG. 3 is a graph illustrating an example of a lifespan curve corresponding to each scenario stored in the storage of an apparatus for diagnosing a state of a battery according to an embodiment of the present disclosure.

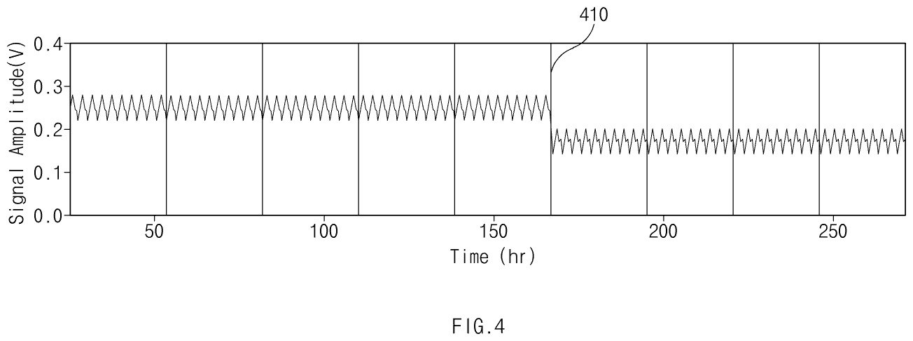

As shown in FIG. 3, the vertical axis represents a SOH (%), and the horizontal axis represents the number of cycles when one cycle is defined as a discharged state from a charged state. In this case, scenario 1 is a case in which the amount of gas generated inside a general battery is small and therefore matches a lifespan curve with a high residual value, and scenario 2 is a case in which the amount of gas generated inside a general battery is large and therefore matches a lifespan curve with a low residual value. For reference, when the amount of gas generated inside a general battery is large, the SA becomes small because ultrasonic reflection and scattering at the solid-gas interface increases. This may also be seen through FIG. 4. In FIG. 4, the vertical axis represents SA (V), the horizontal axis represents time (hr), and reference numeral 410 represents the time point when gas is generated inside a general battery. As shown in FIG. 4, it may be understood that the intensity of the ultrasonic signal (i.e., SA) decreases at the time point 410.

The storage 10 may store various logic, algorithms, and programs used in the process of obtaining an ultrasonic signal from a battery 200 by using the ultrasonic sensor 20, detecting the SA and ToF based on the ultrasonic signal, determining the SOH of the battery, determining a lifespan curve corresponding to the SOH, SA, and ToF of the battery, determining the total energy of the battery 200 by using the lifespan curve, and determining a residual value of the battery 200 based on the total energy of the battery 200.

The storage 10 may store various logic, algorithms, and programs used in the process of obtaining a plurality of first ultrasonic signals in the process of charging the battery 200, obtaining a plurality of second ultrasonic signals in the process of discharging the battery 200, detecting a minimum SA based on the plurality of first ultrasonic signals, detecting a maximum SA based on the plurality of second ultrasonic signals, determining the SOH of the battery 200, and determining a maximum current corresponding to the SOH, maximum SA, and minimum SA of the battery 200.

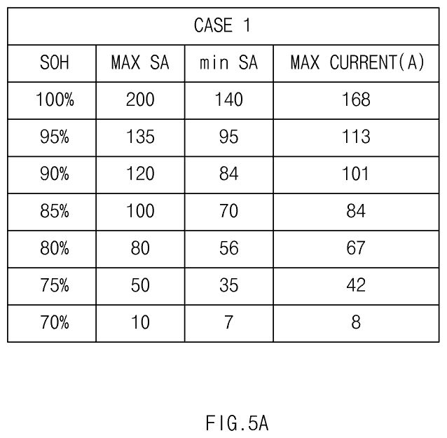

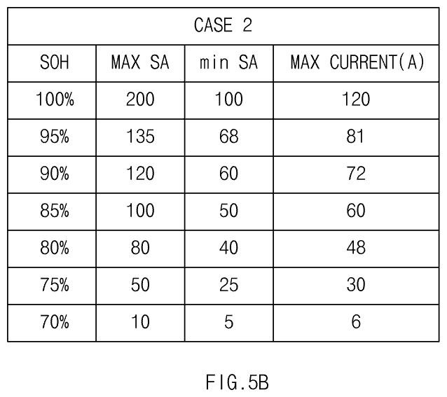

Meanwhile, the storage 10 may store the lookup table in which the SOH of the battery and the maximum current corresponding to the maximum SA and minimum SA are recorded. The lookup tables shown in FIGS. 5 and 5B are examples.

FIGS. 5A and 5B are diagrams illustrating an example of lookup tables stored in the storage of an apparatus for diagnosing a state of a battery according to an embodiment of the present disclosure. Case 1 (FIG. 5A) and case 2 (FIG. 5B) are explained as examples, but the number of cases may increase depending on the SOH, maximum SA, and minimum SA.

As shown in FIGS. 5A and 5B, case 1 and case 2 each includes the maximum SA and minimum SA based on the SOH, and also includes the maximum current corresponding to the SOH and the maximum SA and minimum SA. In this case, the maximum current refers to the maximum current that the battery 200 can supply.

The storage 10 may store various logic, algorithms, and programs used in the process of obtaining a plurality of first ultrasonic signals in the process of charging a target battery, obtaining a plurality of second ultrasonic signals in the process of discharging the target battery, detecting a minimum SA based on the plurality of first ultrasonic signals, detecting a maximum SA based on the plurality of second ultrasonic signals, determining the SOH of the target battery, and determining the maximum current of the target battery based on the lookup table as shown in FIGS. 5A and 5B.

The ultrasonic sensor 20 may generate an ultrasonic signal (e.g., 10 to 1,000 KHz) on one side of the battery 200 and receive the ultrasonic signal transmitted through the battery 200 on an opposite side of the battery 200. That is, the ultrasonic sensor 20 may obtain the ultrasonic signal of the battery 200.

The ultrasonic sensor 20 may include an ultrasonic transmitter attached to one side surface of the battery 200 to transmit an ultrasonic signal, and an ultrasonic receiver attached to an opposite side surface of the battery 200 to receive the ultrasonic signal transmitted through the battery 200.

The output device 30 may output the state of the battery 200 determined by the controller 40. The output device 30 may be provided with an audio output device and a display, and may output the total energy (Wh) of the battery 200 or the maximum current of the battery 200 in voice or on a screen.

The controller 40 may be electrically connected to each component and may perform overall control such that each component performs its function. The controller 40 may be implemented in the form of hardware or software, or may be implemented in a combination of hardware and software. Preferably, the controller 40 may be implemented as a microprocessor, but is not limited thereto.

The controller 40 may obtain the ultrasonic signal from the battery 200 by using the ultrasonic sensor 20, detect the SA and ToF based on the ultrasonic signal, determine the SOH of the battery 200, determine the lifespan curve corresponding to the SOH, SA, and ToF of the battery 200, determine the total energy of the battery 200 by using the lifespan curve, and determining a residual value of the battery 200 based on the total energy of the battery 200. In this case, the controller 40 may determine the residual value of the battery 200 as one of a reuse grade, a remanufacturing grade, and a recycling grade.

In this case, the reuse grade may refer to a state in which the battery 200 is reusable in an electric vehicle, the remanufacturing grade may refer to a state in which the battery 200 is usable in devices (e.g., drones, golf carts, and the like) other than electric vehicles, and the recycling grade may refer to a state in which a lifespan of the battery expires and the battery is usable in producing a new battery.

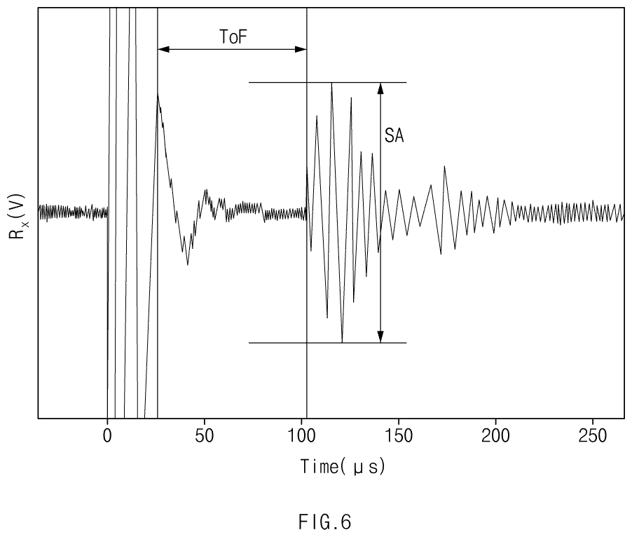

Hereinafter, the operation of the controller 40 will be described in detail with reference to FIGS. 6, 7, and 8.

FIG. 6 is a graph illustrating an example of a process in which a controller provided in an apparatus for diagnosing a state of a battery according to an embodiment of the present disclosure detects the SA and ToF based on an ultrasonic signal of a battery.

In FIG. 6, the vertical axis represents an ultrasonic signal Rₓ (V) of the battery 200, and the horizontal axis represents time (μs). The controller 40 may detect the SA and ToF based on the ultrasonic signal of the battery 200. In this case, when gas is generated inside the battery 200 and a blow-whole exists, ultrasonic reflection and scattering at the solid-gas interface may much stronger than those at the solid-solid and solid-liquid interfaces due to a difference in acoustic impedance, so that the attenuation of SA is greater. Accordingly, the controller 40 detects a smaller SA as the amount of gas generated inside the battery 200 increases.

Meanwhile, in the process of determining the SOH of the battery 200, the controller 40 may use any one scheme among various widely known schemes.

The controller 40 may determine a lifespan curve corresponding to the SOH, SA, and ToF of the battery 200. Referring to FIGS. 2 and 3, for example, when the SOH of the battery 200 is 85% and the SA is 100, the battery 200 may correspond to scenario 1, so that the controller 40 selects a lifespan curve corresponding to the scenario 1. As another example, when the SOH of the battery 200 is 85% and the SA is 5, the battery 200 may correspond to scenario 2, so that the controller 40 selects a lifespan curve corresponding to the scenario 2. In this case, it may be understood that the lifespan curve of the scenario 1 has a higher residual value than the lifespan curve of the scenario 2.

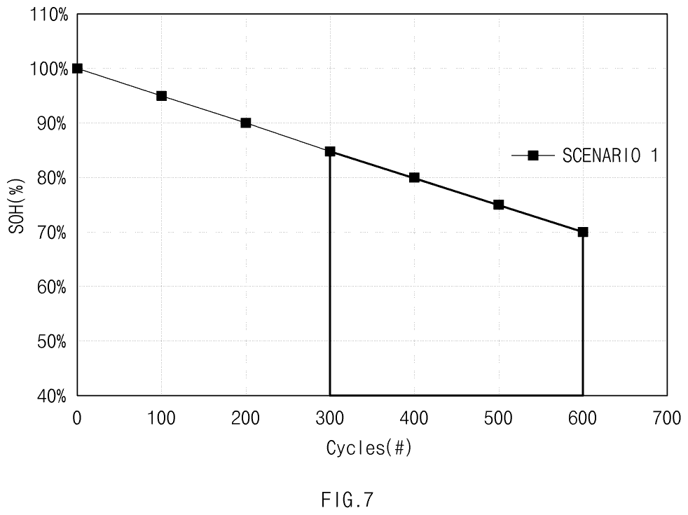

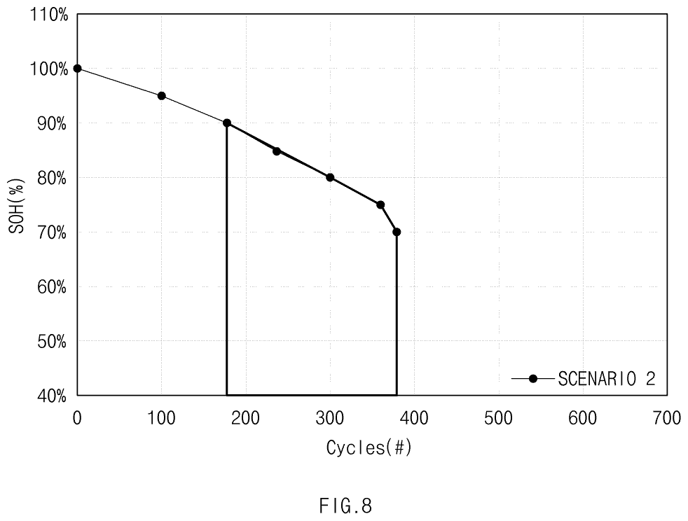

The controller 40 may determine the total energy of the battery 200 by using the lifespan curve. This is as shown in FIGS. 7 and 8.

FIG. 7 is a graph illustrating an example of a process in which a controller provided in an apparatus for diagnosing a state of a battery according to an embodiment of the present disclosure determines the total energy of the battery.

As shown in FIG. 7, the controller 40 determines a reference SOH (e.g., 70%) and also determines a current SOH (e.g., 85%) of the battery 200.

The controller 40 determines the total energy (Wh) from SOH 90 to SOH 70 based on the lifespan curve of the scenario 1. In this case, for example, the controller 40 may determine the total energy (E) of the battery 200 based on following Equation 1.

$$E = \sum S O H ( \% ) \times capacity ( Ah ) \times nominal voltage ( V ) \qquad [ Equation 1 ]$$

Where the unit of total energy (E) is watt-hour, capacity refers to the capacity (Ah) of the battery 200, and nominal voltage refers to the representative voltage (v) of the battery 200.

FIG. 8 is a graph illustrating another example of a process in which a controller provided in an apparatus for diagnosing a state of a battery according to an embodiment of the present disclosure determines the total energy of the battery.

As shown in FIG. 8, the controller 40 determines a reference SOH (e.g., 70%) and also determines a current SOH (e.g., 90%) of the battery 200.

The controller 40 determines the total energy (Wh) from SOH 90 to SOH 70 based on the lifespan curve of the scenario 2. In this case, for example, the controller 40 may determine the total energy (E) of the battery 200 based on Equation 1.

In this case, the total energy determined based on the lifespan curve of the scenario 1 is greater than the total energy determined based on the lifespan curve of the scenario 2, so the residual value of the battery 200 in the scenario 1 is higher than in the scenario 2. The controller 40 may divide the total energy into three sections, and may determine a reuse level when it is included in a first section, a remanufacturing level when it is included in a second section, and a recycling level when it is included in a third section.

Meanwhile, the controller 40 may obtain the plurality of first ultrasonic signals in the process of charging the battery 200, obtain the plurality of second ultrasonic signals in the process of discharging the battery 200, detect the minimum SA based on the plurality of first ultrasonic signals, detect the maximum SA based on the plurality of second ultrasonic signals, determine the SOH of the battery 200, and determine the maximum current corresponding to the SOH, maximum SA, and minimum SA of the battery 200.

Referring to FIGS. 5A and 5B, for example, when the SOH of the battery 200 is 85% and the SA obtained while fully charging and discharging the battery 200 is 100 to 70, the controller 40 may determine that the battery 200 corresponds to case 1 and the maximum current of the battery 200 is 84 A. Therefore, the battery 200 may be applied to a system with a maximum (e.g., required) current of 84 A or less.

As another example, when the SOH of the battery 200 is 85% and the SA obtained while fully charging and discharging the battery 200 is 100 to 50, the controller 40 may determine that the battery 200 corresponds to case 2 and the maximum current of the battery 200 is 60 A. Therefore, the battery 200 may be applied to a system with a maximum (e.g., required) current of 60 A or less.

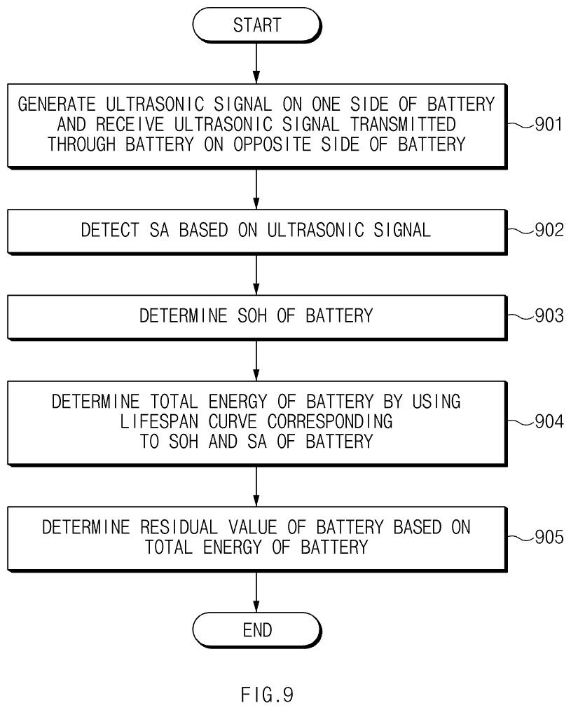

FIG. 9 is a flowchart illustrating a method of diagnosing a state of a battery according to an embodiment of the present disclosure.

First, in 901, the ultrasonic sensor 20 generates an ultrasonic signal on one side of the battery 200 and receives the ultrasonic signal transmitted through the battery 200 on an opposite side of the battery 200.

Then, in 902, the controller 40 detects a SA based on the ultrasonic signal.

In 903, the controller 40 determines a SOH of the battery 200.

Then, in 904, the controller 40 determines the total energy of the battery 200 by using a lifespan curve corresponding to the SOH and SA of the battery 200.

Then, in 905, the controller 40 determines a residual value of the battery based on the total energy of the battery 200.

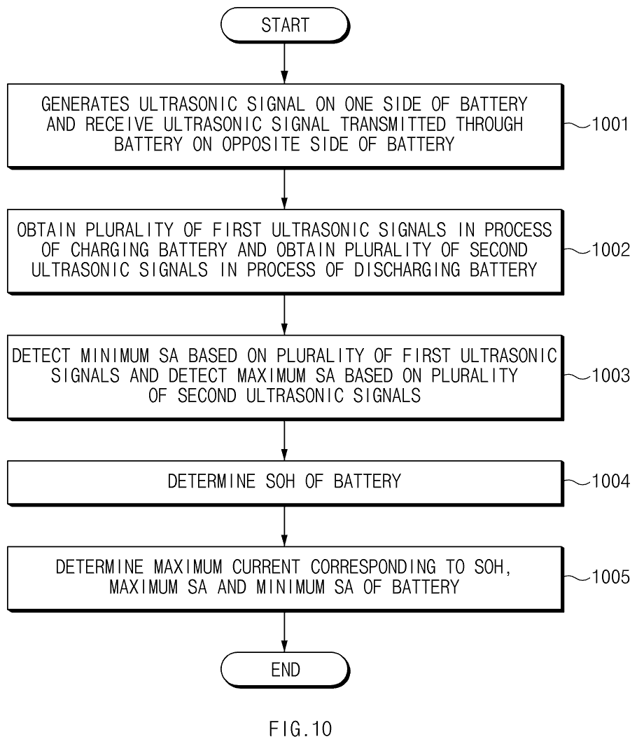

FIG. 10 is a flowchart illustrating a method of diagnosing a state of a battery according to another embodiment of the present disclosure.

First, in 1001, the ultrasonic sensor 20 generates an ultrasonic signal on one side of the battery 200 and receives the ultrasonic signal transmitted through the battery 200 on an opposite side of the battery 200.

Then, in 1002, the controller 40 obtains a plurality of first ultrasonic signals in the process of charging the battery 200 and obtains a plurality of second ultrasonic signals in the process of discharging the battery 200.

Then, in 1003, the controller 40 detects the minimum SA based on the plurality of first ultrasonic signals, and detects the maximum SA based on the plurality of second ultrasonic signals.

Then, in 1004, the controller 40 determines the SOH of the battery 200.

Then, in 1005, the controller 40 determines the maximum current corresponding to the SOH, maximum SA, and minimum SA of the battery 200.

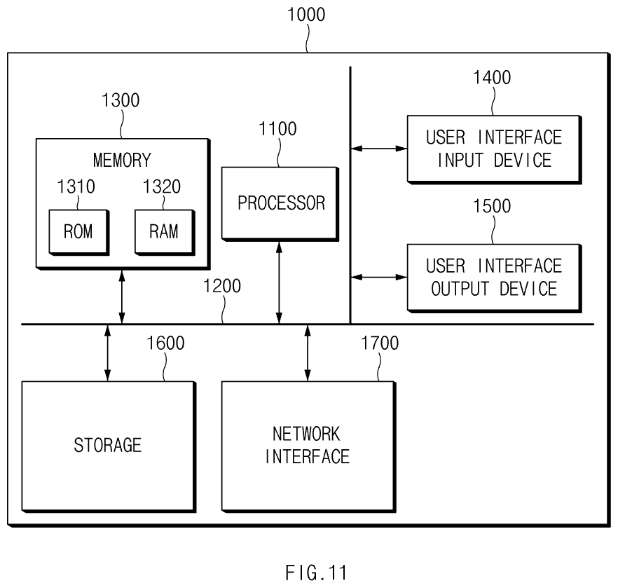

FIG. 11 is a block diagram illustrating a computing system for executing a method of diagnosing a state of a battery according to each embodiment of the present disclosure.

Referring to FIG. 11, as described above, the method of diagnosing a state of a battery according to an embodiment of the present disclosure may be implemented through a computing system 1000. The computing system 1000 may include at least one processor 1100, a memory 1300, a user interface input device 1400, a user interface output device 1500, storage 1600, and a network interface 1700 connected through a system bus 1200.

The processor 1100 may be a central processing unit (CPU) or a semiconductor device that processes instructions stored in the memory 1300 and/or the storage 1600. The memory 1300 and the storage 1600 may include various volatile or nonvolatile storage media. For example, the memory 1300 may include a read only memory (ROM) 1310 and a random access memory (RAM) 1320.

Accordingly, the processes of the method or algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM memory, a flash memory, a ROM memory, an EPROM memory, an EEPROM memory, a register, a hard disk, a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

What is claimed is:

1. An apparatus for diagnosing a state of a battery, the apparatus comprising:
an ultrasonic sensor configured to generate an ultrasonic signal on one side of the battery and receive an ultrasonic signal transmitted through the battery from an opposite side of the battery; and
a controller configured to detect a signal amplitude (SA) based on the ultrasonic signal, determine a state of health (SOH) of the battery, determine total energy of the battery by using a lifespan curve corresponding to the SOH and SA of the battery, and determine a residual value of the battery based on the total energy of the battery.

2. The apparatus of claim 1, further comprising a memory configured to store a plurality of lifespan curves corresponding to the SOH and SA.

3. The apparatus of claim 2, wherein the controller is configured to select the lifespan curve corresponding to the SOH and SA of the battery.

4. The apparatus of claim 1, wherein the controller is configured to determine the residual value of the battery as one of a reuse grade, a remanufacturing grade, and a recycling grade.

5. The apparatus of claim 4, wherein the reuse grade refers to a state in which the battery is reusable in an electric vehicle, the remanufacturing grade refers to a state in which the battery is usable in devices other than the electric vehicle, and the recycling grade refers to a state in which a lifespan of the battery expires and the battery is usable in producing a new battery.

6. The apparatus of claim 1, wherein the controller is configured to determine the residual value of the battery to be lower than when gas is not generated in the battery, taking into account that the SA is reduced when the gas is generated inside the battery.

7. A method of diagnosing a state of a battery, the method comprising:
generating, by an ultrasonic sensor, an ultrasonic signal on one side of the battery and receiving an ultrasonic signal transmitted through the battery from an opposite side of the battery;
detecting, by a controller, a signal amplitude (SA) based on the ultrasonic signal;
determining, by the controller, a state of health (SOH) of the battery;
determining, by the controller, total energy of the battery by using a lifespan curve corresponding to the SOH and SA of the battery; and
determining, by the controller, a residual value of the battery based on the total energy of the battery.

8. The method of claim 7, further comprising storing, by a memory, a plurality of lifespan curves corresponding to the SOH and SA.

9. The method of claim 8, wherein the determining of the total energy of the battery includes selecting, by the controller, the lifespan curve corresponding to the SOH and SA of the battery.

10. The method of claim 7, wherein the determining of the residual value of the battery includes determining the residual value of the battery as one of a reuse grade, a remanufacturing grade, and a recycling grade.

11. The method of claim 10, wherein the reuse grade refers to a state in which the battery is reusable in an electric vehicle, the remanufacturing grade refers to a state in which the battery is usable in devices other than the electric vehicle, and the recycling grade refers to a state in which a lifespan of the battery expires and the battery is usable in producing a new battery.

12. The method of claim 7, wherein the determining of the residual value of the battery includes determining the residual value of the battery to be lower than when gas is not generated in the battery, taking into account that the SA is reduced when the gas is generated inside the battery.

13. An apparatus for diagnosing a state of a battery, the apparatus comprising:
an ultrasonic sensor configured to generate an ultrasonic signal on one side of the battery and receive an ultrasonic signal transmitted through the battery from an opposite side of the battery; and
a controller configured to obtain a plurality of first ultrasonic signals while charging the battery, obtain a plurality of second ultrasonic signals while discharging the battery, detect a minimum signal amplitude (SA) based on the plurality of first ultrasonic signals, detect a maximum SA based on the plurality of second ultrasonic signals, determine a state of health (SOH) of the battery, and determine a maximum current corresponding to the SOH, maximum SA, and minimum SA of the battery.

14. The apparatus of claim 13, further comprising a memory configured to store a look-up table in which a maximum current corresponding to the SOH, the maximum SA, and the minimum SA is recorded.

15. The apparatus of claim 14, wherein the controller is configured to determine the maximum current corresponding to the SOH, maximum SA, and minimum SA of the battery based on the look-up table.

16. The apparatus of claim 13, further comprising an output device configured to output the maximum current.

17. A method of diagnosing a state of a battery, the method comprising:
generating, by an ultrasonic sensor, an ultrasonic signal on one side of the battery and receiving an ultrasonic signal transmitted through the battery from an opposite side of the battery;
obtaining, by a controller, a plurality of first ultrasonic signals while charging the battery and obtaining a plurality of second ultrasonic signals while discharging the battery;
detecting, by the controller, a minimum signal amplitude (SA) based on the plurality of first ultrasonic signals, and detecting a maximum SA based on the plurality of second ultrasonic signals;
determining, by the controller, a state of health (SOH) of the battery; and
determining, by the controller, a maximum current corresponding to the SOH, maximum SA, and minimum SA of the battery.

18. The method of claim 17, further comprising:
storing, by a memory, a look-up table in which a maximum current corresponding to the SOH, the maximum SA, and the minimum SA is recorded.

19. The method of claim 18, wherein the determining of the maximum current includes determining the maximum current corresponding to the SOH, maximum SA, and minimum SA of the battery based on the look-up table.

20. The method of claim 17, further comprising:
outputting, by an output device, the maximum current.
